(19) United States
(12) Patent Application Publication
(10) Pub. No.: US 2019/0378749 A1
(43) Pub. Date: Dec. 12, 2019

(54) MICRO-VACUUM MODULE FOR SEMICONDUCTOR DEVICE TRANSFER AND METHOD FOR TRANSFERRING SEMICONDUCTOR DEVICE USING THE MICRO-VACUUM MODULE

(71) Applicant: Korea Advanced Institute of Science and Technology, Daejeon (KR)

(72) Inventors: Keon Jae Lee, Daejeon (KR); Han Eol Lee, Daejeon (KR); Tae Jin Kim, Daejeon (KR); Jung Ho Shin, Daejeon (KR); Sang Hyun Park, Daejeon (KR)

(21) Appl. No.: 16/225,178

(22) Filed: Dec. 19, 2018

(30) Foreign Application Priority Data
Jun. 12, 2018 (KR) 10-2018-0067701
Jul. 3, 2018 (KR) 10-2018-0076935

(51) Int. Cl. H01L 21/683; H01L 21/67

(52) U.S. Cl. CPC H01L 21/6838; H01L 21/67144

(57) ABSTRACT

The present disclosure provides a method for transferring a semiconductor device using a micro-vacuum module, wherein the micro-vacuum module includes: a vacuum-forming substrate having a plurality of through-holes, which are connected to an external pump module and a vacuum control unit, formed; and a pattern-forming unit equipped with a single channel or a plurality of independent channels, which is coupled to the vacuum-forming substrate, wherein the plurality of channels are formed to be communicated respectively to a plurality of vacuum holes which have a smaller size than the size of a semiconductor device to be transferred, and the plurality of vacuum holes, having a diameter smaller than 100 μm, are contacted to a micro semiconductor device having a width and a length of 100 μm or smaller and the micro semiconductor device is transferred using vacuum adsorption.

### CROSS-REFERENCE TO RELATED APPLICATION

This application claims priority of Korean Patent Application No. 10-2018-0067701, filed on Jun. 12, 2018, and priority of Korean Patent Application No. 10-2018-0076935, filed on Jul. 3, 2018, in the KIPO (Korean Intellectual Property Office), the disclosure of which is incorporated herein entirely by reference.

### GOVERNMENT LICENSE RIGHTS

This research was supported by Creative Materials Discovery Program through the National Research Foundation of Korea (NRF) funded by Ministry of Science and ICT (2016M3D1A1900035).

### BACKGROUND OF THE INVENTION

### Field of the Invention

The present disclosure relates to a method for fabricating a micro-vacuum module for semiconductor device transfer, which enables easy transfer of various electronic devices including semiconductor devices onto a target substrate by micro-vacuum adsorption.

### Description of the Related Art

Printable semiconductor devices include thin-film transistors, microLEDs, batteries, memories, etc. These semiconductor devices are generally formed on hard mother substrates including silicon, SOI and glass substrates through common semiconductor processes and then transferred to the desired target substrates, which may be silicon, SOI, glass or plastic substrates, through printing of various electronic devices.

The existing methods of transferring semiconductor devices employ polymer stamping, electrostatic force or electromagnetic force.

First, in the method of printing an electronic device through polymer stamping, the device is fabricated on a hard mother substrate including silicon, SOI and glass substrates by the general CMOS process. The fabricated device is detached from the mother substrate by adhering thereto a stamp made of a polymer such as PDMS, a shape-memory polymer, etc.

The detached semiconductor device is printed on a target substrate such as a silicon, SOI, glass or plastic substrate. The polymer stamp may be prepared into various forms including a mesa structure, etc. depending on needs.

However, when the polymer stamp is used, the devices that can be transferred are very limited, such as a lateral microLED with low efficiency, and transfer efficiency is decreased as the size of the stamp is increased. In addition, there are problems in that the polymer stamp may be deformed mechanically after repeated use and it is difficult to selectively transfer only the desired device from among many devices.

In the method of printing an electronic device using electrostatic force, a semiconductor device is fabricated on a hard mother substrate including silicon, SOI and glass substrates by the general CMOS process. After contacting an electrostatic transfer module on the fabricated device and forming electrostatic force between the device and the module by applying a voltage, the electronic device is detached from the mother substrate using the electrostatic force. The detached semiconductor device is printed on a target substrate such as a silicon, SOI, glass or plastic substrate. Direct current (DC) or alternating current (AC) may be used for the electrostatic transfer module and the device may be printed on the target substrate by grounding the module.

However, when the electrostatic transfer module is used, the devices that can be transferred are very limited, such as a lateral microLED with low efficiency, and transfer efficiency is low. In addition, there is a risk of the breakdown of the electronic device because of the high voltage applied to form the electrostatic force.

In the method of printing an electronic device using electromagnetic force, a semiconductor device is fabricated on a hard mother substrate including silicon, SOI and glass substrates by the general CMOS process. The fabricated device is transferred onto a carrier substrate and then a layer of a magnetic material such as Ni is formed on the device. After contacting an electromagnetic transfer module thereto and forming electromagnetic or attractive force between the device and the module by applying a voltage, the electronic device is detached from the mother substrate using the force.

The detached semiconductor device is printed on a target substrate such as a silicon, SOI, glass or plastic substrate. Because a coil is equipped inside the electromagnetic transfer module, electromagnetic force is generated when a current is applied to the electromagnetic transfer module. The device may be printed on the target substrate by removing the electromagnetic force by shutting off the current to the electromagnetic transfer module.

However, when the electromagnetic transfer module is used, the devices that can be transferred are very limited, such as a lateral microLED with low efficiency, and transfer efficiency is low because the transfer has to be conducted twice. In addition, this method is not applicable to a semiconductor device with a size of 30 μm or smaller.

Korean Patent Registration No. 10-1307481 (Methods and devices for fabricating and assembling printable semiconductor elements) discloses a method for fabricating structures and devices such as electronic devices including semiconductor elements on a target substrate using a polymer stamp such as PDMS.

### SUMMARY OF THE INVENTION

The present disclosure is directed to providing a method for fabricating a micro-vacuum module for semiconductor device transfer, which enables easy transfer of large-area electronic devices regardless of the type of the electronic devices.

The present disclosure is also directed to providing a method which enables selective transfer of semiconductor devices using the micro-vacuum module fabricated according to the method for fabricating a micro-vacuum module for semiconductor device transfer.

In an aspect, the present disclosure provides a method for transferring a semiconductor device using a micro-vacuum module, wherein the micro-vacuum module includes: a vacuum-forming substrate having a plurality of through-holes, which are connected to an external pump module and a vacuum control unit, formed; and a pattern-forming unit equipped with a single channel or a plurality of independent channels, which is coupled to the vacuum-forming substrate, wherein the plurality of channels are formed to be communicated respectively to a plurality of vacuum holes which have a smaller size than the size of a semiconductor device to be transferred, and the plurality of vacuum holes, having a diameter smaller than 100 μm, are contacted to a micro semiconductor device having a width and a length of 100 μm or smaller and the micro semiconductor device is transferred using vacuum adsorption.

In another aspect, the present disclosure provides a method for fabricating a micro-vacuum module for semiconductor device transfer, including: a step of forming a hole array serving as holes for forming micro-vacuum on a base substrate; a step of attaching the base substrate onto a carrier substrate using a sacrificial layer; a step of forming a pattern layer capable of covering the hole array formed on the base substrate; a step of attaching a process substrate having through-holes connected to an external pump module and a vacuum control unit to the base substrate; and a step of removing the sacrificial layer and the pattern layer.

The hole array may be formed by a process selected from a Si Bosch process, a laser micromachining process and a patterning process using an epoxy polymer.

The hole array formed on the base substrate has a diameter of 1 μm to 1 mm and an area smaller than the area of a semiconductor device to be transferred.

The hole array formed on the base substrate has a diameter smaller than 100 μm and the semiconductor device which is a microLED has a width and a length of 100 μm or smaller.

In another aspect, the present disclosure provides a method for fabricating a micro-vacuum module for semiconductor device transfer, including: a step of forming a material that can be used as a sacrificial layer on a carrier substrate; a step of forming a hole array serving as holes for forming micro-vacuum on the sacrificial layer; a step of forming a channel in a direction not covering the hole array formed on the carrier substrate; a step of attaching the carrier substrate with the channel formed to a process substrate; and a step of separating the carrier substrate by removing the sacrificial layer.

The hole array has a diameter of 1 μm to 1 mm and an area smaller than the area of a semiconductor device to be transferred.

The hole array has a diameter smaller than 100 μm and the semiconductor device which is a microLED has a width and a length of 100 μm or smaller.

The micro-vacuum module for semiconductor device transfer fabricated according to the present disclosure can transfer all types of electronic devices including thin-film type, packaged unit type, etc. Because the transfer module is fabricated on a hard substrate, the module size is not limited and large-area transfer is possible. Also, selective transfer of the electronic device is possible by selectively releasing vacuum, if necessary.

During the transfer process using the micro-vacuum module for semiconductor device transfer fabricated according to the present disclosure, the adhesive force between the module and the electronic device by vacuum can be adjusted simply by controlling the suction power of a vacuum pump and the damage to the micro-sized semiconductor device can be minimized.

In addition, the transfer is very simple because no additional deposition or patterning process is necessary and the efficiency of transfer is high because the transfer is performed only once.

The transfer method using the micro-vacuum module for semiconductor device transfer according to the present disclosure is applicable to various electronic devices regardless of shape or size and is also applicable to very wide applications including VLSI (very-large-scale integration), displays, etc.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1-7 illustrate the steps of a method for fabricating a micro-vacuum module for semiconductor device transfer according to an exemplary embodiment of the present disclosure.

FIGS. 8-14 illustrate the steps of a method for fabricating a micro-vacuum module for semiconductor device transfer according to another exemplary embodiment of the present disclosure.

FIGS. 15-19 illustrate the steps of a method for fabricating a micro-vacuum module for semiconductor device transfer according to another exemplary embodiment of the present disclosure.

FIG. 20 shows a process of transferring a semiconductor device using a micro-vacuum module fabricated according to the present disclosure.

FIG. 21 shows an optical microscopic image of the channel portion of a micro-vacuum module for semiconductor device transfer with a sacrificial layer and a polymer pattern removed through a solution process in FIG. 7.

FIG. 22 shows an optical microscopic image of the channel portion of a micro-vacuum module for semiconductor device transfer with a carrier substrate having a channel layer formed and a process substrate attached in FIG. 12.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

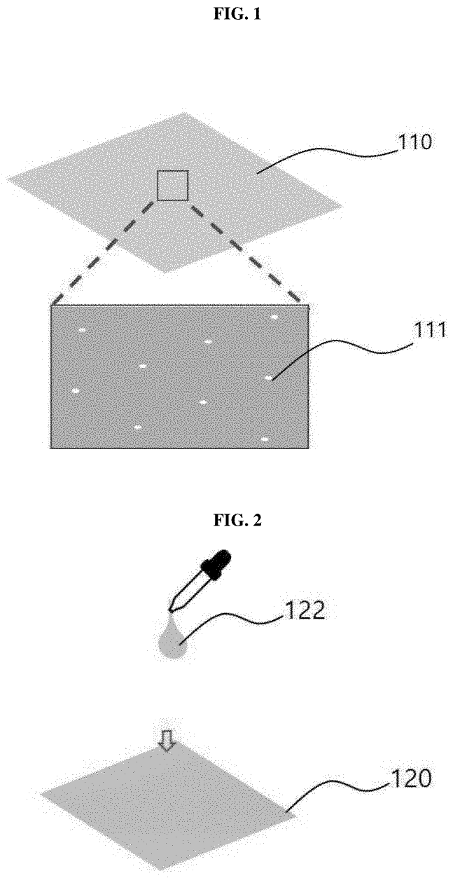

FIGS. 1-7 illustrate the steps of a method for fabricating a micro-vacuum module for semiconductor device transfer according to an exemplary embodiment of the present disclosure.

A step of forming a hole array on a base substrate 110 is described referring to FIG. 1. FIG. 1 shows a portion of a base substrate 110 with a hole array 111 formed thereon.

The hole array 111 is formed on the base substrate 110, which is easily machinable, e.g., silicon, glass, acryl, etc., through a reactive-ion etching process or a process using laser.

The hole array 111 formed on the base substrate 110 has a diameter or a side ranging from 1 μm to 1 mm. The hole array 111 is formed according to the cell of the device to be transferred. The area of each hole of the hole array 111 should not be larger than the area of the device. The hole array 111 serves as holes for forming micro-vacuum.

For example, the hole array 111 is formed on the base substrate 110 in singular or plural numbers with a diameter smaller than 100 μm and is contacted with a microLED (PLED) having a width and a length of 100 μm or smaller.

The hole array 111 may be formed by a Si Bosch process, a laser micromachining process, a patterning process using an epoxy polymer (SU8, etc.), etc.

The microLED may be a thin-film microLED with a size of 5 μm or smaller.

Referring to FIG. 2, a sacrificial layer solution 122 which exhibits adhesive property and can be removed with a specific solution is formed uniformly on a carrier substrate 120. The material used for the sacrificial layer solution 122 should not react with an adhesive used in the subsequent process and the specific solution used to remove the sacrificial layer solution 122 should not react with the adhesive, too. The sacrificial layer solution 122 may be a sacrificial layer which exhibits adhesive property and can be removed with a specific solution. Specifically, for the sacrificial layer solution 122, PMMA (poly(methyl methacrylate)), a photoresist or PVA (polyvinyl alcohol) may be used.

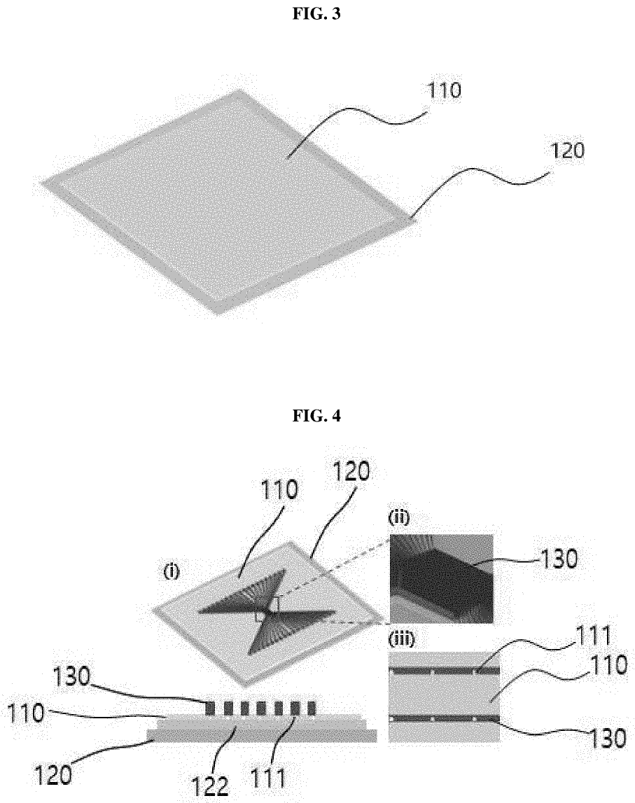

Referring to FIG. 3, the base substrate 110 is attached onto the carrier substrate 120.

Referring to FIG. 4, a channel layer 130 capable of covering the hole array 111 on the base substrate 110 is formed using a polymer which is capable of forming a pattern through photolithography on the base substrate 110 attached onto the carrier substrate 120 (FIG. 4 (i)).

FIG. 4 (ii) shows an image of a pattern at the center portion of the channel layer 130. FIG. 4 (iii) shows an image of a pattern at the center portion of the channel layer 130 seen from above.

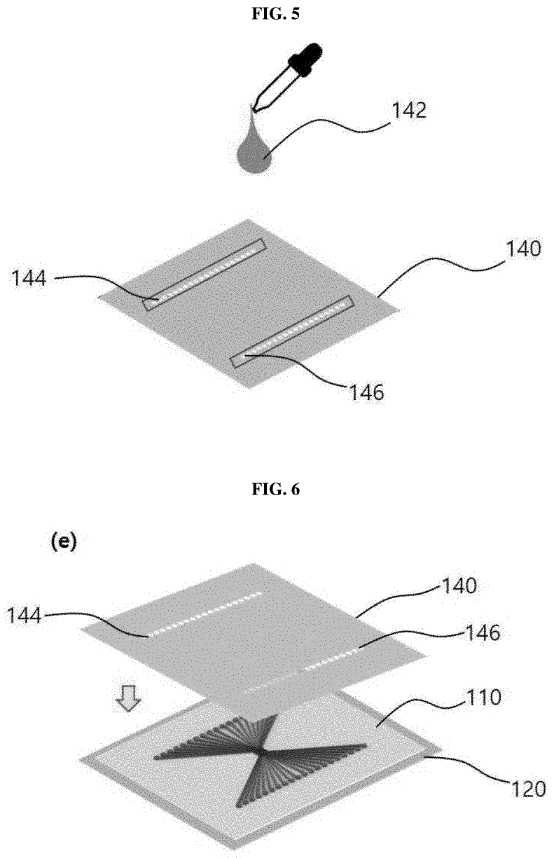

Referring to FIG. 5, an adhesive 142 is applied onto a process substrate 140 with a first through-hole 144 connected to an external pump module and a second through-hole 146 connected to a vacuum control unit formed. The process substrate 140 should be transparent when a UV-curable adhesive is used. When other adhesives are used, it needs not be transparent as long as the adhesive can be applied uniformly by spin coating. The process substrate may also be referred to as a process forming substrate.

Referring to FIG. 6, the process substrate 140 is attached to the base substrate 110 with the channel layer 130 formed. During this process, the process substrate 140 is inverted such that the adhesive 142 is contacted with the top surface of the base substrate 110.

In the process where the process substrate 140 is attached to the base substrate 110, the adhesive 142 should be filled between the channel layer 130 formed of a photosensitive material. If the channel layer 130 is removed after the adhesive 142 is cured, the adhesive 142 is formed with a shape opposite to that of the channel layer 130 and a plurality of channel holes 132 are formed in the space that has been occupied by the channel layer 130. Overall, the adhesive 142 with the channel holes 132 formed between the process substrate 140 and the base substrate 110 serves as a support layer and the hole array 111 is communicated respectively to the plurality of channel holes 132.

Accordingly, for selective transfer channel by channel, vacuum should be formed for each channel pattern or line pattern formed along the plurality of channel holes 132. Here, the channel pattern or line pattern may be defined as a connected structure of the channel hole 132 and the hole array 111.

In order to separate the devices transferred from a mother substrate channel by channel, the devices should be lifted with the adsorptive force delivered through the hole array 111. Therefore, the width of the channel hole 132 covering the hole array 111 is determined within a range not affecting the hole array 111 present on the other adjacent channel pattern.

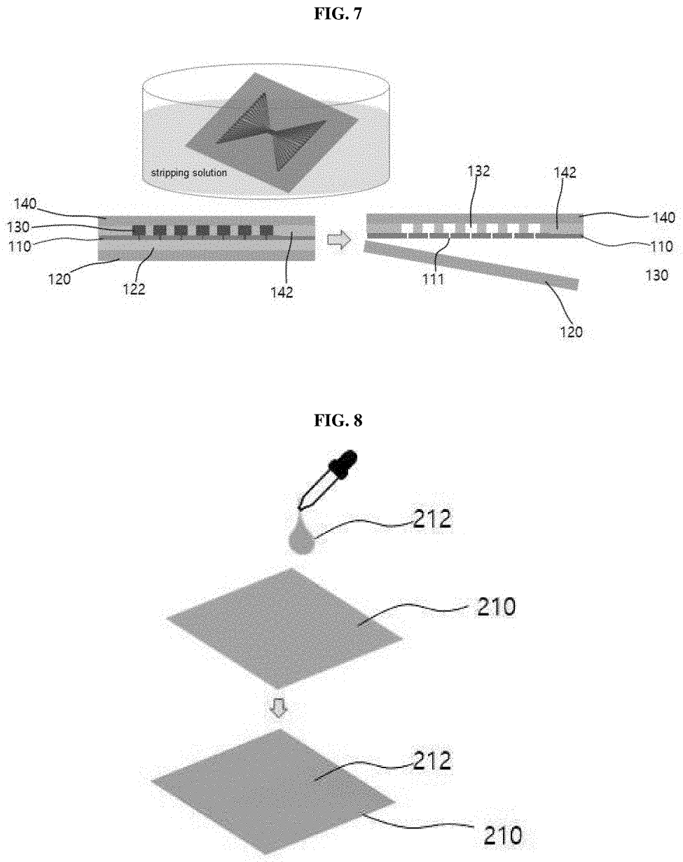

Referring to FIG. 7, after the adhesive 142 is cured, the carrier substrate 120 is separated from the base substrate 110 using a solution which reacts with the material of the sacrificial layer solution 122. Then, in order to remove the channel layer 130 formed by photolithography, the formed pattern is removed using a solution which reacts with the material used to form the channel layer.

When the same solution is used to remove the materials used to form the sacrificial layer solution 122 and the channel layer 130, the process of separating the base substrate 110 and the carrier substrate 120 and the process of removing the pattern formed by photolithography may be conducted at the same time.

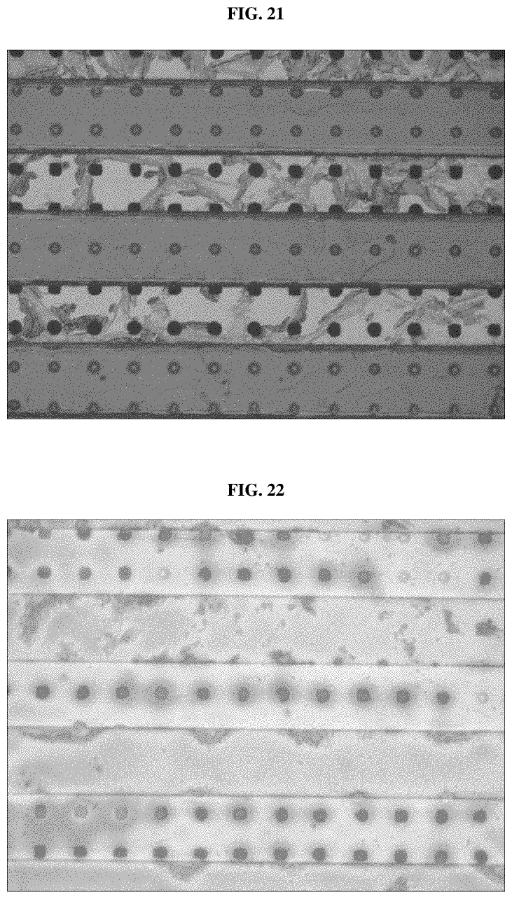

FIG. 21 shows an optical microscopic image of the channel portion of the micro-vacuum module for semiconductor device transfer with the sacrificial layer and the polymer pattern removed through the solution process in FIG. 7.

FIGS. 8-14 illustrate a method for fabricating a micro-vacuum module for semiconductor device transfer according to another exemplary embodiment of the present disclosure.

Referring to FIG. 8, a material that can be used as a sacrificial layer 212 is formed on a carrier substrate 210. The sacrificial layer 212 contains hydrogenated amorphous silicon (a-Si:H), a photosensitive material, PVA (poly(vinyl alcohol)), etc. that can be removed or separated in the subsequent process. When the sacrificial layer contains hydrogenated amorphous silicon (a-Si:H), it may be separated using a laser. When other materials are used for the sacrificial layer, they may be removed using solvents that react with the respective materials.

The carrier substrate 210 may be any substrate which is surface-treated such that the material used as the sacrificial layer is or can be applied uniformly by spin coating.

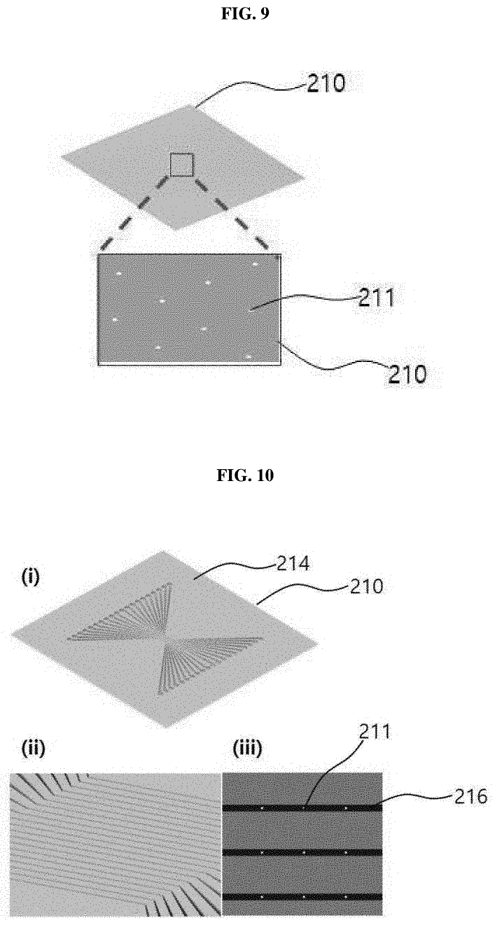

Referring to FIG. 9, a hole array 211 is formed on the carrier substrate 210 by photolithography.

The hole array 211 formed on the carrier substrate 210 has a diameter or a side ranging from 1 μm to 1 mm. The hole array 211 is formed according to the cell of the device to be transferred and the area of each hole should not be larger than the area of the device.

Referring to FIG. 10, a channel layer 216 is formed in a direction not covering the hole array 211 on the carrier substrate 210 using a polymer 214 which is capable of forming the channel layer 216 on the carrier substrate 210 by photolithography (FIG. 10 (i)).

FIG. 10 (ii) shows an image of a pattern at the center portion of the channel layer 216. FIG. 10 (iii) shows an image of a pattern at the center portion of the channel layer 216 seen from above.

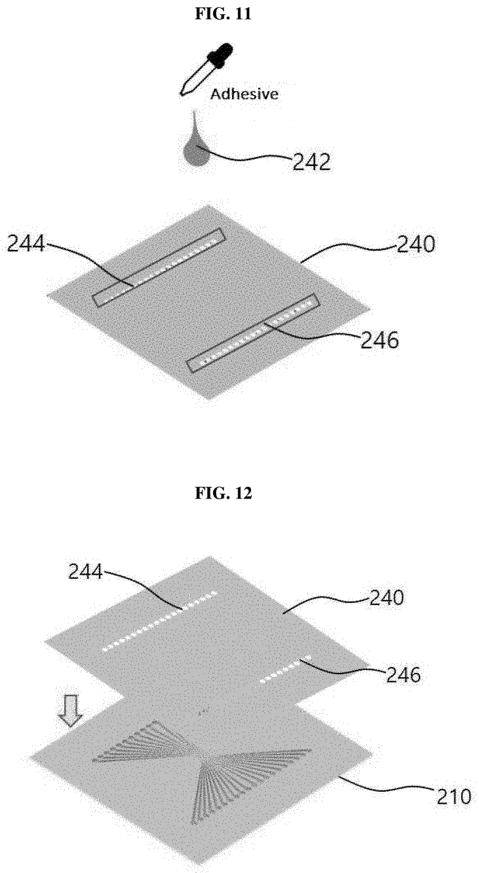

Referring to FIG. 11, an adhesive 242 is applied onto a process substrate 240 with a first through-hole 244 connected to an external pump module and a second through-hole 246 connected to a vacuum control unit formed. The process substrate 240 should be transparent when a UV-curable adhesive is used. When other adhesives are used, it needs not be transparent as long as the adhesive can be applied uniformly by spin coating.

Referring to FIG. 12, the process substrate 240 is attached to the carrier substrate 210 with the channel layer formed. During this process, the process substrate 240 is inverted such that the adhesive 242 is contacted with the top surface of the carrier substrate 210.

FIG. 22 shows an optical microscopic image of the channel portion of the micro-vacuum module for semiconductor device transfer with the carrier substrate having the channel layer formed and the process substrate attached.

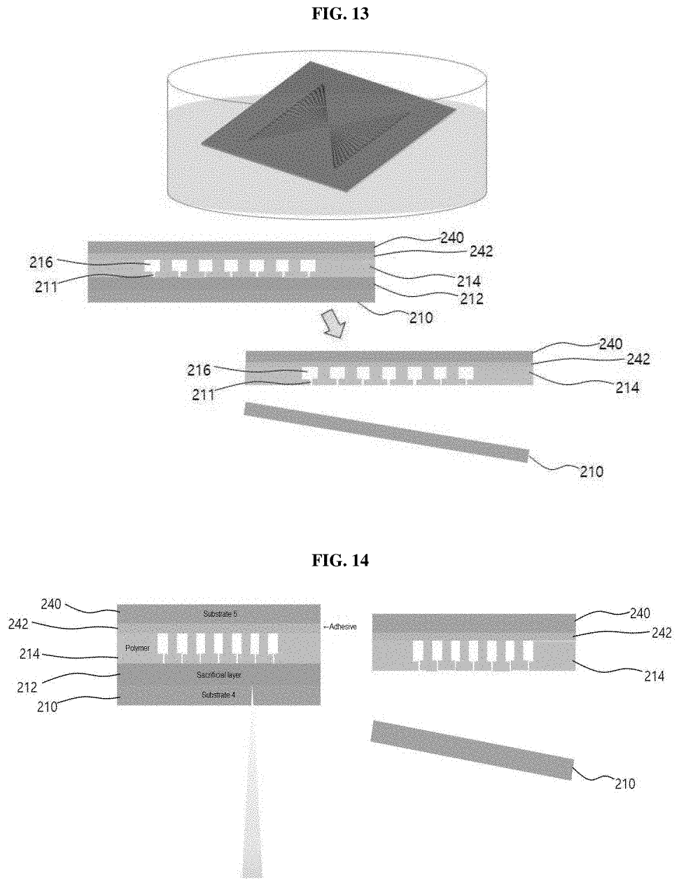

Referring to FIG. 13, after the adhesive 242 is cured, the structure formed on the sacrificial layer 212 is separated from the carrier substrate 210 by removing the sacrificial layer 212 using a solution which reacts only with the sacrificial layer 212. When hydrogenated amorphous silicon (a-Si:H) is used as the sacrificial layer, the sacrificial layer is separated from the carrier substrate 210 by irradiating laser to the sacrificial layer and then the remaining sacrificial layer is removed through sonication.

Through this, the channel layer 216 is fixed on the process substrate 240 by the cured adhesive 242.

Referring to FIG. 14, when silicon oxide is used as the sacrificial layer 212, the sacrificial layer 212 is separated from the carrier substrate 210 by irradiating laser to the sacrificial layer and then the remaining sacrificial layer 212 is removed using a solution containing hydrofluoric acid.

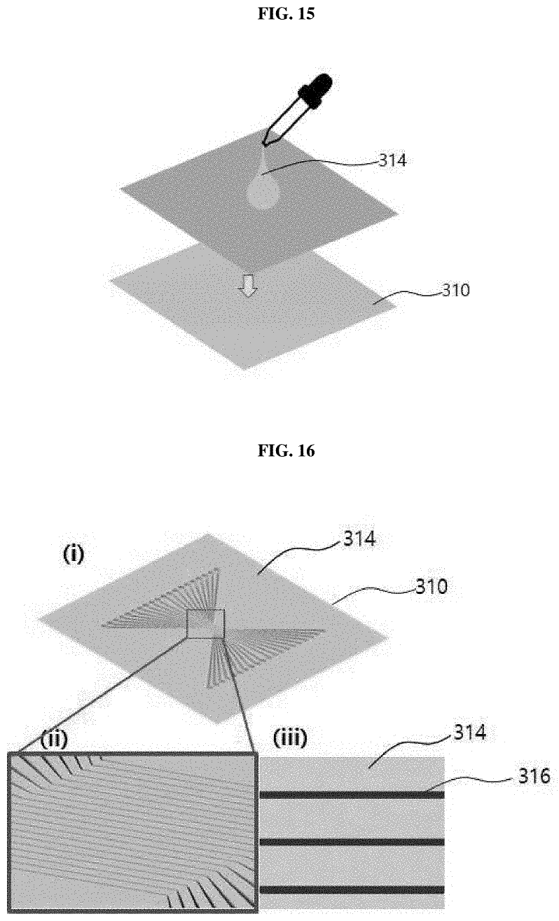

FIGS. 15-19 illustrate a method for fabricating a micro-vacuum module for semiconductor device transfer according to another exemplary embodiment of the present disclosure.

Referring to FIG. 15, a polymer 314 enabling channel formation is spin-coated on a base substrate 310 by photolithography. The base substrate 310 should be a transparent substrate so as to allow processing using laser.

Referring to FIG. 16 (i), a desired channel layer 316 is formed on the polymer 314 by photolithography. FIG. 16 (ii) shows an image of a pattern of the channel portion of the channel layer 316 and FIG. 16 (iii) shows an image of the channel portion of the channel layer 316 seen from above.

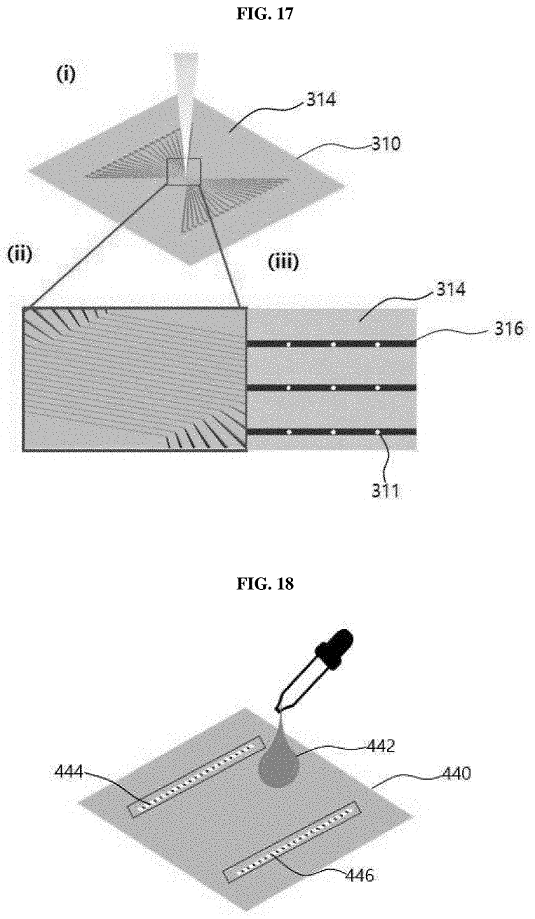

Referring to FIG. 17 (i), a hole array 311 is formed by forming a plurality of holes on the channel layer 316 with predetermined intervals using laser. The laser may be ultraviolet (UV), infrared (IR) or green laser having a wavelength of 100-1064 nm and a pulse duration of 10-12-10-8 seconds.

FIG. 17 (ii) shows an image of the center portion of the channel layer 316 and FIG. 17 (iii) shows an image of a pattern of the center portion of the channel layer 316 seen from above.

Referring to FIG. 18, an adhesive 342 is applied onto a process substrate 340 with a first through-hole 344 connected to an external pump module and a second through-hole 346 connected to a vacuum control unit formed. The process substrate 340 should be transparent when a UV-curable adhesive is used. When other adhesives are used, it needs not be transparent as long as the adhesive can be applied uniformly by spin coating.

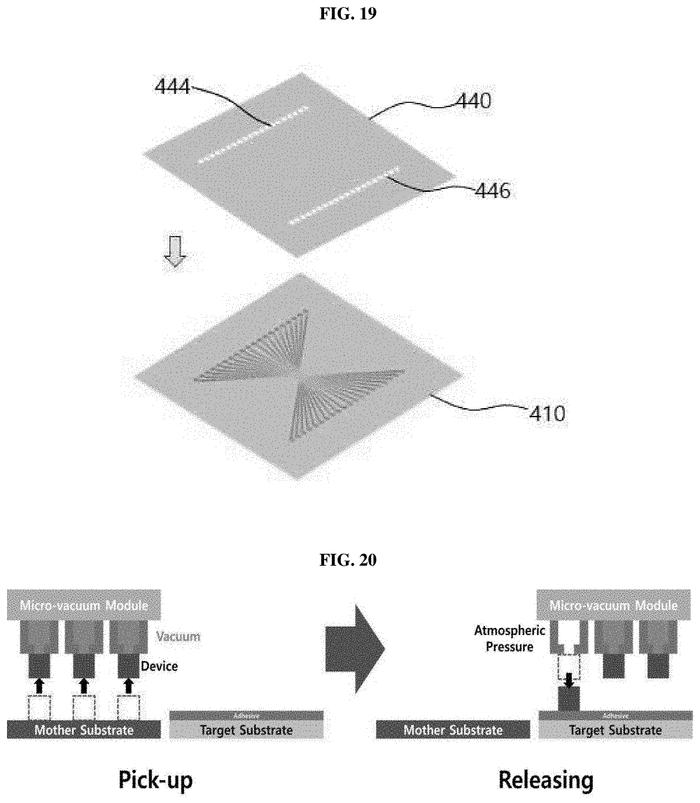

Referring to FIG. 19, the process substrate 340 is attached to the base substrate 310 with the channel layer formed. During this process, the process substrate 340 is inverted such that the adhesive 342 is contacted with the top surface of the base substrate 310.

FIG. 20 shows a process of transferring a semiconductor device using the micro-vacuum module fabricated according to the present disclosure.

By using vacuum formed in the micro-channel of the micro-vacuum module according to the present disclosure, an electronic device formed on a hard mother substrate may be separated and then printed onto a target substrate.

The micro-channel is formed by a hole array 111, 211 formed on a base substrate 110, 210.

Hereinafter, a process of transferring a semiconductor device is described in detail.

First, a printable semiconductor device is fabricated on a hard mother substrate.

After accurately aligning the hole array of the micro-vacuum module and the semiconductor device array by adjusting locations, the hole array is contacted with the semiconductor device.

By forming vacuum by taking out air inside the micro-channel by connecting a pump to the micro-vacuum module, the semiconductor device is attached to the hole array of the micro-vacuum module.

The separation of the semiconductor device can be conducted on a wafer scale and, if necessary, selective separation is possible by selectively forming vacuum. The adhesive force of the semiconductor device increases in proportion to the amount of the air taken out by the pump. If the first adhesive force between the micro-vacuum module and the semiconductor device is larger than the second adhesive force between the semiconductor device and the mother substrate, the semiconductor device can be separated from the mother substrate.

After the semiconductor device is transferred to the micro-vacuum module attached therebelow, the location on the target substrate may be adjusted accurately and the attached electronic device can be released accurately on the desired location by releasing vacuum. Full transfer is possible by entirely releasing the vacuum formed in the micro-vacuum module and, if necessary, selective transfer is possible by selectively releasing the vacuum.

After the semiconductor device is transferred to the target substrate, a device fabrication process may be conducted, if necessary.

As described above, the micro-vacuum module for semiconductor device transfer fabricated according to the present disclosure can transfer all types of electronic devices including thin-film type, packaged unit type, etc. Because the transfer module is fabricated on a hard substrate, the module size is not limited and large-area transfer is possible. Also, selective transfer of the electronic device is possible by selectively releasing vacuum, if necessary.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method for transferring a semiconductor device using a micro-vacuum module, wherein the micro-vacuum module comprising:
a vacuum-forming substrate having a plurality of through-holes, which are connected to an external pump module and a vacuum control unit, formed; and
a pattern-forming unit equipped with a single channel or a plurality of independent channels, which is coupled to the vacuum-forming substrate,
wherein the plurality of channels are formed to be communicated respectively to a plurality of vacuum holes which have a smaller size than the size of a semiconductor device to be transferred,
wherein the plurality of vacuum holes, having a diameter smaller than 100 μm, are contacted to a micro semiconductor device having a width and a length of 100 μm or smaller and the micro semiconductor device is transferred using vacuum adsorption.

2. The method for transferring a semiconductor device of claim 1, wherein the transfer is possible channel by channel if the channel of the vacuum module is plural and the transfer is possible at once if it is singular.

3. The method for transferring a semiconductor device of claim 1, wherein the plurality of vacuum holes are formed by a Si Bosch process.

4. The method for transferring a semiconductor device of claim 1, wherein the plurality of vacuum holes are formed by a laser micromachining process.

5. The method for transferring a semiconductor device of claim 1, wherein the plurality of vacuum holes are formed by a patterning process using an epoxy polymer.

6. The method for transferring a semiconductor device of claim 1, wherein the semiconductor device is a thin-film microLED having a thickness of 5 μm or smaller.

7. A method for fabricating a micro-vacuum module for semiconductor device transfer, comprising:
forming a hole array serving as holes for forming micro-vacuum on a base substrate;
attaching the base substrate onto a carrier substrate using a sacrificial layer;
forming a pattern layer capable of covering the hole array formed on the base substrate;
attaching a process substrate having through-holes connected to an external pump module and a vacuum control unit to the base substrate; and
removing the sacrificial layer and the pattern layer.

8. The method for fabricating a micro-vacuum module for semiconductor device transfer of claim 7, wherein the hole array is formed by a process selected from a Si Bosch process, a laser micromachining process and a patterning process using an epoxy polymer.

9. The method for fabricating a micro-vacuum module for semiconductor device transfer of claim 7, wherein the hole array formed on the base substrate has a diameter of 1 μm to 1 mm and an area smaller than the area of a semiconductor device to be transferred.

10. The method for fabricating a micro-vacuum module for semiconductor device transfer of claim 9, wherein the hole array formed on the base substrate has a diameter smaller than 100 μm and the semiconductor device which is a microLED has a width and a length of 100 μm or smaller.

11. A method for fabricating a micro-vacuum module for semiconductor device transfer, comprising:
forming a material that can be used as a sacrificial layer on a carrier substrate;
forming a hole array serving as holes for forming micro-vacuum on the sacrificial layer;
forming a channel in a direction not covering the hole array formed on the carrier substrate;
attaching the carrier substrate with the channel formed to a process substrate; and
separating the carrier substrate by removing the sacrificial layer.

12. The method for fabricating a micro-vacuum module for semiconductor device transfer of claim 11, wherein the hole array is formed using an epoxy polymer and has a diameter of 1 μm to 1 mm and an area smaller than the area of a semiconductor device to be transferred.

13. The method for fabricating a micro-vacuum module for semiconductor device transfer of claim 12, wherein the hole array has a diameter smaller than 100 μm and the semiconductor device which is a microLED has a width and a length of 100 μm or smaller.

14. The method for fabricating a micro-vacuum module for semiconductor device transfer of claim 11, wherein the hole array is formed by a process selected from a Si Bosch process, a laser micromachining process and a patterning process using an epoxy polymer.

15. The method for fabricating a micro-vacuum module for semiconductor device transfer of claim 11, wherein the channel is formed by a process selected from a Si etching process, a laser micromachining process and a patterning process using an epoxy polymer.

16. A method for fabricating a micro-vacuum module for semiconductor device transfer, comprising:
forming a channel on a base substrate;
forming a hole array with a predetermined interval corresponding to the channel formed on the base substrate; and
attaching a process substrate with through-holes connected to an external pump module and a vacuum control unit formed to the base substrate.

17. The method for fabricating a micro-vacuum module for semiconductor device transfer of claim 16, wherein the hole array is formed by a process selected from a Si Bosch process and a laser micromachining process.

18. The method for fabricating a micro-vacuum module for semiconductor device transfer of claim 16, wherein the channel is formed by a process selected from a Si etching process, a laser micromachining process and a patterning process using an epoxy polymer.

19. The method for fabricating a micro-vacuum module for semiconductor device transfer of claim 16, wherein the hole array is formed using an epoxy polymer and has a diameter of 1 μm to 1 mm and an area smaller than the area of a semiconductor device to be transferred.

20. The method for fabricating a micro-vacuum module for semiconductor device transfer of claim 19, wherein the hole array has a diameter smaller than 100 μm and the semiconductor device which is a microLED has a width and a length of 100 μm or smaller.
